(19) United States
(12) Patent Application Publication
(10) Pub. No.: US 2022/0016802 A1
(43) Pub. Date: Jan. 20, 2022

(54) METHOD FOR SLICING WORKPIECE AND WIRE SAW

(71) Applicant: SHIN-ETSU HANDOTAI CO., LTD., Tokyo (JP)

(72) Inventor: Kenji KOBAYASHI, Nishigo-mura (JP)

(73) Assignee: SHIN-ETSU HANDOTAI CO., LTD., Tokyo (JP)

(21) Appl. No.: 17/413,810

(22) PCT Filed: Dec. 25, 2019
(86) PCT No.: PCT/JP2019/050777

§ 371 Date: Jun. 14, 2021

(30) Foreign Application Priority Data
Jan. 15, 2019 (JP) 2019-004381

(51) Int. Cl. B28D 5/00; B28D 5/04; B24B 27/06

(52) U.S. Cl. CPC B28D 5/007; B28D 5/042; B24B 27/06; B28D 5/0064; B28D 5/0082

(57) ABSTRACT

A method for slicing a workpiece includes feeding and slicing a workpiece held by a workpiece holder with a bonding member therebetween, while reciprocatively traveling a fixed abrasive grain wire wound around multiple grooved rollers to form a wire row, so that the workpiece is sliced at multiple positions simultaneously. The bonding member has a grindstone part. The method includes, after the workpiece is sliced and before it is drawn out from the wire row, a fixed-abrasive-grain removal step of pressing the wire against the grindstone to remove fixed abrasive grains from the wire while reciprocatively traveling. In the fixed-abrasive-grain removal step, the wire rate is 100 m/min. or less, and the load on each line of the wire is 30 g or more. The method prevents a sliced workpiece from catching a wire and from causing saw mark and wire break in drawing out the wire after slicing.

### TECHNICAL FIELD

The present invention relates to a method for slicing a workpiece and a wire saw.

### BACKGROUND ART

As means for slicing off wafers from a silicon ingot, a compound semiconductor ingot, or the like, wire saws have been conventionally known. In such a wire saw, a wire row is formed by winding a slicing wire around multiple rollers in many turns, the slicing wire is driven in an axial direction thereof at a high speed, and a workpiece is fed to the wire row for slicing, while a slurry is being supplied appropriately, whereby this workpiece is sliced at wire positions simultaneously (see, for example, Patent Document 1).

Here, FIG. 6 shows a schematic drawing of an example of a conventional general wire saw. As shown in FIG. 6, this wire saw 101 is mainly constituted of: a wire 102 for slicing a the workpiece W′; grooved rollers 103, 103′ around which the wire 102 is wound; a wire row 130 formed by winding the wire 102 around the multiple grooved rollers 103, 103′; a tension-adjusting mechanism 104 for adjusting the tension of the wire 102; a workpiece-feeding mechanism 105 for feeding the workpiece W′ to be sliced downward; and a slurry supply mechanism 106 for supplying a slurry during the slicing.

The wire 102 is reeled out from one wire reel 107, passes through a traverser 108, a pulley 109, and the tension-adjusting mechanism 104, and wound around the grooved rollers 103, 103′ in approximately 300 to 500 turns. Then, the wire 102 is taken up by a wire reel 107′ through another set of a tension-adjusting mechanism 104′, a pulley 109′, and a traverser 108′.

Additionally, each of the grooved rollers 103, 103′ is a roller provided by press-fitting a polyurethane resin around a cylinder made of steel and forming grooves on a surface thereof at a substantially fixed pitch. The grooved rollers 103, 103′ are configured such that the wound wire 102 can be driven in one direction or reciprocating directions in a predetermined cycle by a motor 110 for driving the grooved rollers.

Moreover, like a workpiece holder shown in FIG. 7 which is used in the conventional general wire saw, the workpiece-feeding mechanism 105 in FIG. 6 for feeding the workpiece W′ downward has a workpiece holder 114 constituted of a workpiece-holding portion 112 and a workpiece plate 113. To the workpiece plate 113, the workpiece W′ is adhered with a bonding member (beam) 120 interposed between the workpiece W′ bonded thereto and the workpiece plate 113.

When the workpiece W′ is to be sliced, the workpiece W′ is held and pushed down by the workpiece-feeding mechanism 105, and fed to the wire row 130 wound around the grooved rollers 103, 103′. Such a wire saw 101 is used to apply appropriate tension to the wire 102 with the tension-adjusting mechanism 104, the slurry is supplied from the slurry supply mechanism 106 while the wire 102 travels in the reciprocating directions by driving motors 111, 111′, and the workpiece W′ is fed for slicing by the workpiece-feeding mechanism 105, thereby slicing the workpiece W′.

On the other hand, there is also known a method for slicing a workpiece by using a fixed abrasive grain wire which has diamond abrasive grains or the like secured to a surface of the wire, instead of using slurry containing abrasive grains. This has been partially put into practical use for slicing small-diameter ingots with diameters of approximately 150 mm or less.

In this slicing using the fixed abrasive grain wire, a general wire saw can be used as it is, by attaching the fixed abrasive grain wire to the wire saw as shown in FIG. 6 in place of the steel wire and changing the slurry to a coolant, such as cooling water, which does not contain abrasive grains.

### CITATION LIST

### Patent Literature

Patent Document 1: Japanese Unexamined Patent Application Publication No. H9-262826

### SUMMARY OF INVENTION

### Technical Problem

Slicing with the fixed abrasive grain wire has many advantages: since loose abrasive grains are not used, the amount of industrial waste is small in environmental aspects; and the processing rate is high in comparison with processing with a wire saw utilizing loose abrasive grains. However, in the wire saw as shown in FIG. 6, since the workpiece W′ is sliced by pressing and moving against the single wire 102 wound around the grooved rollers 103, 103′, the workpiece W′ at the end of slicing is placed on a lower side of the wire 102 against which the workpiece W′ has been pushed. Accordingly, to take out the workpiece W′, the sliced workpiece W needs to be drawn out by moving up the workpiece W such that the wire 102 passes through gaps between wafers sliced off from the workpiece W′, and is then relatively drawn out downward.

At the time of drawing out the wire in the wire saw using loose abrasive grains, a gap (clearance) corresponding to a width of each loose abrasive grain G is formed between the wire 102 and the workpiece W′ as shown in FIG. 8(a). Hence, extraction of the wire 102 is relatively easy.

However, in the wire saw using fixed abrasive grains, little gap is formed between a fixed abrasive grain wire 402 and a workpiece W′ as shown in FIG. 8(b). Hence, the fixed abrasive grain wire 402 is hard to be drawn out. Further, since the fixed abrasive grains of the fixed abrasive grain wire have a cutting ability by themselves, the fixed abrasive grain wire 402 cut into the workpiece W′, making it harder to draw out the fixed abrasive grain wire 402. Accordingly, the fixed abrasive grain wire 402 is caught by the workpiece W′ and rises. If the fixed abrasive grain wire 402 is drawn out in this state, a workpiece cut section is damaged, what is called saw mark is formed on the cut section, and thereby Warp is degraded to impair quality. Furthermore, when the fixed abrasive grain wire 402 further rises, the wire may be broken. The wire break results in great losses; for example, an additional operation is required to re-wind the fixed abrasive grain wire around the grooved rollers, and an extra length of the fixed abrasive grain wire is required for the re-winding.

The present invention has been made in view of the problems as described above. An object of the present invention is to provide a method for slicing a workpiece and a wire saw which prevent a sliced workpiece from catching a fixed abrasive grain wire and from causing saw mark and wire break of the fixed abrasive grain wire in drawing out the fixed abrasive grain wire after slicing the workpiece.

### Solution to Problem

To achieve the object, the present invention provides a method for slicing a workpiece with a wire saw which includes a wire row formed by winding a fixed abrasive grain wire having abrasive grains secured to a surface thereof around a plurality of grooved rollers, the method comprising feeding a workpiece to the wire row for slicing the workpiece held by a workpiece holder with a bonding member bonded to the workpiece, while allowing the fixed abrasive grain wire to reciprocatively travel in an axial direction thereof, thereby slicing the workpiece at a plurality of positions aligned in an axial direction of the workpiece simultaneously,

wherein the bonding member has a grindstone as a part,

the method comprises, after the workpiece is sliced and before the workpiece is drawn out from the wire row, a fixed-abrasive-grain removal step of pressing the wire row against the grindstone to remove the fixed abrasive grains from the fixed abrasive grain wire while the fixed abrasive grain wire is reciprocatively traveling, and

in the fixed-abrasive-grain removal step, the fixed abrasive grain wire is traveled at a wire rate of 100 m/min. or less, and the wire row is pressed against the grindstone at a load of 30 g or more for each line of the fixed abrasive grain wire.

According to such a method for slicing a workpiece, after a workpiece is sliced and before the workpiece is drawn out through the wire row, fixed abrasive grains are removed from the fixed abrasive grain wire surface, so that a gap (clearance) is successfully formed between the wire and the workpiece. In addition, as the fixed abrasive grains having a cutting ability are removed, cutting into the workpiece by the fixed abrasive grain wire is successfully prevented. These enable drawing of the workpiece without being caught by the fixed abrasive grain wire, and make it possible to avoid saw mark formation and wire break of the fixed abrasive grain wire, which otherwise occur if the workpiece is caught by the fixed abrasive grain wire.

Moreover, in this event, a WA grindstone is preferably used as the grindstone.

Consequently, the use of a WA (White Alundum) grindstone as the grindstone enables effective removal of the fixed abrasive grains on the fixed abrasive grain wire surface, and the workpiece can be drawn out while more reliably prevented from being caught by the fixed abrasive grain wire.

Further, in the method for slicing a workpiece, the workpiece is preferably drawn out from the wire row through a portion of the fixed abrasive grain wire from which the fixed abrasive grains have been removed in the fixed-abrasive-grain removal step.

According to such a method for slicing a workpiece, the workpieces are drawn out through positions on the fixed abrasive grain wire surface where the fixed abrasive grains are removed. This makes it possible to draw out the workpiece while further reliably preventing the workpiece from being caught by the fixed abrasive grain wire.

Moreover, the present invention provides a wire saw comprising:

a wire row formed of a fixed abrasive grain wire which has abrasive grains secured to a surface thereof and is wound around a plurality of grooved rollers; and

a workpiece-feeding mechanism configured to press a workpiece against the wire row, the workpiece being held by a workpiece holder with a bonding member bonded to the workpiece, wherein

the workpiece-feeding mechanism feeds the workpiece for slicing to the wire row while the fixed abrasive grain wire reciprocatively travels in an axial direction thereof, thereby slicing the workpiece at a plurality of positions aligned in an axial direction of the workpiece simultaneously,

the bonding member has a grindstone as a part,

the wire saw comprises a unit configured to remove fixed abrasive grains from the fixed abrasive grain wire by pressing the wire row against the grindstone while the fixed abrasive grain wire is reciprocatively traveling, and

when the fixed abrasive grains are removed, the fixed abrasive grain wire is traveled at a wire rate of 100 m/min. or less, and the wire row is pressed against the grindstone at a load of 30 g or more for each line of the fixed abrasive grain wire.

The inventive wire saw includes the unit configured to remove fixed abrasive grains from the fixed abrasive grain wire surface. This enables gap formation between the wire and the workpiece, and removal of the fixed abrasive grains having a cutting ability, so that it is possible to prevent the fixed abrasive grain wire from cutting into the workpiece. These enable drawing of the workpiece without being caught by the fixed abrasive grain wire, and make it possible to avoid saw mark formation and wire break of the fixed abrasive grain wire, which otherwise occur if the workpiece is caught by the fixed abrasive grain wire.

Moreover, in this case, the grindstone is preferably a WA grindstone.

Such a structure enables effective removal of fixed abrasive grains on the fixed abrasive grain wire surface, and the workpiece can be drawn out while more reliably prevented from being caught by the fixed abrasive grain wire.

Further, the wire saw preferably comprises a controller configured to control drawing of the workpiece from the wire row through a portion where the fixed abrasive grains have been removed from the fixed abrasive grain wire by the unit configured to remove fixed abrasive grains.

The controller controls positions where the workpieces are drawn out through portions on the fixed abrasive grain wire surface from which the fixed abrasive grains are removed, and the wire saw including such a controller is capable of drawing out the workpiece while further reliably preventing the workpiece from being caught by the fixed abrasive grain wire.

### Advantageous Effects of Invention

As described above, according to the inventive method for slicing a workpiece and the inventive wire saw, a workpiece is successfully drawn out without being caught by the fixed abrasive grain wire when the workpiece is drawn out from the wire row. This makes it possible to avoid saw mark formation and wire break of the fixed abrasive grain wire, which would otherwise occur if the workpiece is caught by the fixed abrasive grain wire.

### BRIEF DESCRIPTION OF DRAWINGS

FIG. 1 is a schematic drawing showing an example of a wire saw that can be used for the inventive method for slicing a workpiece.

FIG. 2(a) is a drawing showing a positional relationship between a workpiece and a fixed abrasive grain wire at the end of slicing the workpiece, (b) is a drawing showing a state of the workpiece and the fixed abrasive grain wire when the wire is caught, and (c) is a drawing showing a positional relationship between the workpiece and the fixed abrasive grain wire at the end of drawing out the workpiece.

FIG. 3 is a schematic drawing showing an example of a workpiece holder of the inventive wire saw.

FIG. 4 is a schematic drawing showing a holder with a grindstone bonded thereto, which was used in Experimental Examples 1, 2.

FIG. 5(a) is an SEM observation result of a fixed abrasive grain wire before a reciprocal movement test in Experimental Example 1, and (b) is an SEM observation result of the fixed abrasive grain wire after the reciprocal movement test in Experimental Example 1.

FIG. 6 is a schematic drawing showing an example of a general wire saw.

FIG. 7 is a schematic drawing showing an example of a workpiece holder of the general wire saw.

FIG. 8(a) is an explanatory drawing for illustrating wire extraction with a wire saw using loose abrasive grains (loose abrasive grain system); and (b) is an explanatory drawing for illustrating wire extraction with a wire saw using a fixed abrasive grain wire (fixed abrasive grain system).

FIG. 9 is a schematic drawing showing a workpiece holder used in Comparative Example.

### DESCRIPTION OF EMBODIMENTS

Hereinafter, embodiments of the present invention will be described, but the present invention is not limited thereto.

As noted above, in slicing a workpiece using a fixed abrasive grain wire, there are problems that when the sliced workpiece is drawn out from the wire row, the fixed abrasive grain wire is caught by the workpiece, so that a saw mark is formed on the cut section and the fixed abrasive grain wire is broken.

Thus, the present inventor has earnestly studied to solve such problems. Consequently, the inventor has found that, when very hard, abrasion-resistant abrasive grains, for example, diamond, used on a fixed abrasive grain wire are sufficiently removed from the fixed abrasive grain wire, a workpiece can be drawn out without the fixed abrasive grain wire being caught by the workpiece. Based on this finding, the inventor has arrived at a method including: slicing a workpiece, then pressing a wire row against a grindstone, and reciprocatively traveling the fixed abrasive grain wire to remove the fixed abrasive grains. Thus, the present invention has been completed.

Specifically, the present invention is a method for slicing a workpiece with a wire saw which includes a wire row formed by winding a fixed abrasive grain wire having abrasive grains secured to a surface thereof around a plurality of grooved rollers, the method comprising feeding a workpiece to the wire row for slicing the workpiece held by a workpiece holder with a bonding member bonded to the workpiece, while allowing the fixed abrasive grain wire to reciprocatively travel in an axial direction thereof, thereby slicing the workpiece at a plurality of positions aligned in an axial direction of the workpiece simultaneously,

wherein the bonding member has a grindstone as a part,

the method comprises, after the workpiece is sliced and before the workpiece is drawn out from the wire row, a fixed-abrasive-grain removal step of pressing the wire row against the grindstone to remove the fixed abrasive grains from the fixed abrasive grain wire while the fixed abrasive grain wire is reciprocatively traveling, and

in the fixed-abrasive-grain removal step, the fixed abrasive grain wire is traveled at a wire rate of 100 m/min. or less, and the wire row is pressed against the grindstone at a load of 30 g or more for each line of the fixed abrasive grain wire.

In addition, the present invention is a wire saw comprising:

a wire row formed of a fixed abrasive grain wire which has abrasive grains secured to a surface thereof and is wound around a plurality of grooved rollers; and

a workpiece-feeding mechanism configured to press a workpiece against the wire row, the workpiece being held by a workpiece holder with a bonding member bonded to the workpiece, wherein

the workpiece-feeding mechanism feeds the workpiece for slicing to the wire row while the fixed abrasive grain wire reciprocatively travels in an axial direction thereof, thereby slicing the workpiece at a plurality of positions aligned in an axial direction of the workpiece simultaneously,

the bonding member has a grindstone as a part,

the wire saw comprises a unit configured to remove fixed abrasive grains from the fixed abrasive grain wire by pressing the wire row against the grindstone while the fixed abrasive grain wire is reciprocatively traveling, and

when the fixed abrasive grains are removed, the fixed abrasive grain wire is traveled at a wire rate of 100 m/min. or less, and the wire row is pressed against the grindstone at a load of 30 g or more for each line of the fixed abrasive grain wire.

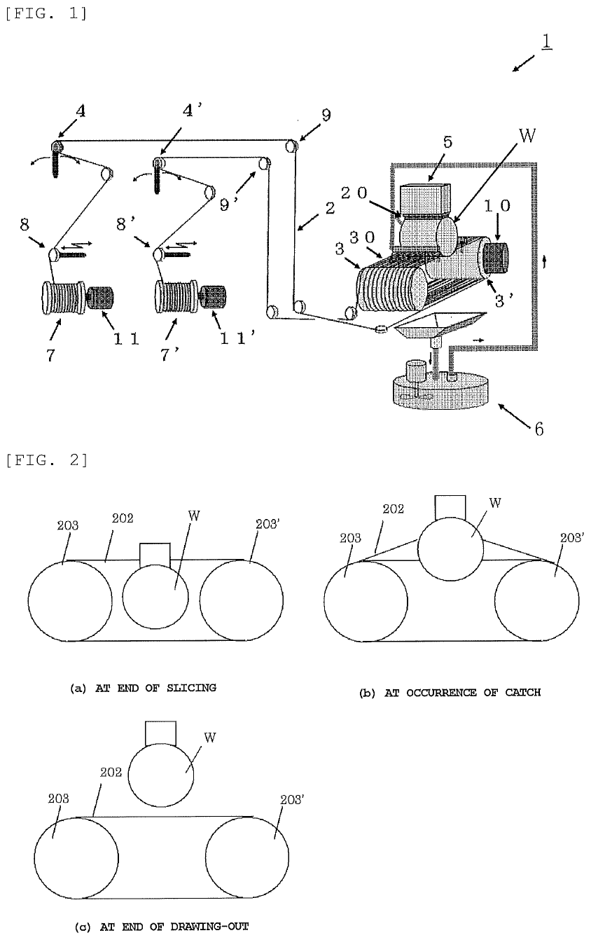

First, a wire saw which can be used in the inventive method for slicing a workpiece will be described with reference to FIG. 1. As shown in FIG. 1, a wire saw 1 according to the present invention is constituted of: a fixed abrasive grain wire 2 configured to slice a workpiece W; grooved rollers 3, 3′ around which the fixed abrasive grain wire 2 is wound; a wire row 30 formed of the fixed abrasive grain wire 2 wound around the multiple grooved rollers 3, 3′; a tension-adjusting mechanism 4 configured to adjust the tension of the fixed abrasive grain wire 2; a workpiece-feeding mechanism 5 configured to downwardly feed the workpiece W to be sliced while holding the workpiece by using a workpiece holder with a bonding member 20 interposed between the workpiece bonded thereto and the workpiece holder; and a coolant-supplying mechanism 6 configured to supply a coolant, such as cooling water, during slicing.

The fixed abrasive grain wire 2 is reeled out from one wire reel 7, passes through a traverser 8, a pulley 9, and the tension-adjusting mechanism 4, and wound around the grooved rollers 3, 3′ in approximately 300 to 500 turns. Then, the fixed abrasive grain wire 2 passes through another set of a tension-adjusting mechanism 4′, a pulley 9′, and a traverser 8′, and is taken up by a wire reel 7′.

Such a wire saw 1 slices the workpiece W simultaneously at multiple positions aligned in an axial direction of the workpiece W when the workpiece W is fed to the wire row 30 for slicing, while the fixed abrasive grain wire 2 reciprocatively travels in an axial direction of the fixed abrasive grain wire 2. The fixed abrasive grain wire 2 is reciprocatively traveled, for example, by a method in which the fixed abrasive grain wire 2 wound between the multiple grooved rollers 3, 3′ is advanced in one direction by a predetermined length and then retreated in the other direction by a length shorter than the aforementioned advancing amount. This is regarded as one feed cycle, and this cycle is repeated to feed out the wire in one direction. The grooved roller 3′ is configured to drive the fixed abrasive grain wire 2 wound therearound in reciprocating directions in a predetermined period by using a motor 10 configured to drive the grooved rollers.

FIGS. 2(a) and (c) are drawings each showing a positional relationship between a workpiece W and a fixed abrasive grain wire 202 wound around the grooved rollers 203, 203′ at the end of slicing the workpiece or at the end of drawing out the workpiece. As shown in FIG. 2(a), at the end of slicing, the workpiece W is located below the wire row. Thus, to take out the workpiece W, the fixed abrasive grain wire 202 needs to be relatively drawn downward by moving up the workpiece W such that the fixed abrasive grain wire 202 passes through gaps between wafers of the workpiece, which has been sliced into the wafers.

However, in the case of a conventional wire saw using a fixed abrasive grain wire, little clearance is formed between the fixed abrasive grain wire 202 and the workpiece W (see FIG. 8(b)), so that the fixed abrasive grain wire 202 is caught by the workpiece W and rises as shown in FIG. 2(b). Consequently, saw mark is formed on a cut section of the workpiece W, or the wire is broken.

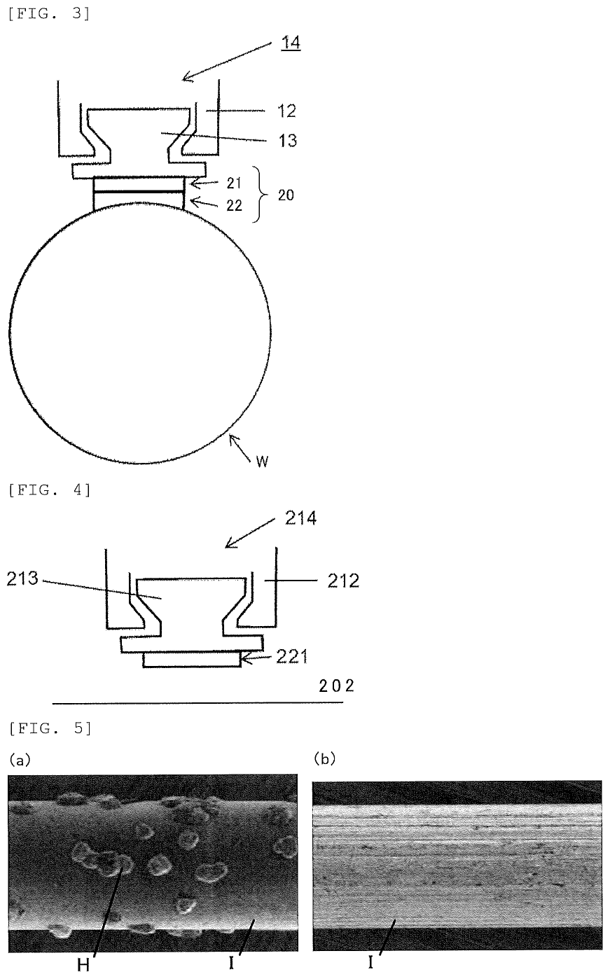

FIG. 3 shows a workpiece holder usable in the inventive wire saw. The inventive wire saw has a grindstone 21 as a part of the bonding member 20, and further includes a unit configured to remove fixed abrasive grains from the fixed abrasive grain wire by pressing the wire row against the grindstone 21 while the fixed abrasive grain wire travels reciprocatively. Note that the workpiece holder 14 may be constituted of a workpiece-holding portion 12 and a workpiece plate 13. Additionally, the bonding member 20 may have a resin 22, or the like, to adhere the workpiece W to the bonding member 20. Moreover, examples of the unit configured to remove fixed abrasive grains can include means for pressing the wire row 30 against the grindstone 21 by utilizing the workpiece-feeding mechanism 5, and other similar means.

Further, in the inventive wire saw when the fixed abrasive grains are removed, the fixed abrasive grain wire is traveled at a wire rate of 100 m/min. or less, and the wire row is pressed against the grindstone at a load of 30 g or more for each line of the fixed abrasive grain wire.

The inventive wire saw 1 as described above includes the unit configured to remove fixed abrasive grains from the surface of the fixed abrasive grain wire 2. Thus, a gap is formed between the wire and the workpiece W, and removal of the fixed abrasive grains having cutting ability is achieved. This makes it possible to prevent the fixed abrasive grain wire 2 from cutting into the workpiece W. These allow the workpiece W to be drawn out without being caught by the fixed abrasive grain wire 2, and can avoid saw mark formation and wire break of the fixed abrasive grain wire, which otherwise occur if the fixed abrasive grain wire 2 is caught by the workpiece W.

Herein, the grindstone of the inventive wire saw 1 is not particularly limited, as long as it is capable of removing the fixed abrasive grains from the fixed abrasive grain wire 2. Nevertheless, the grindstone is preferably a WA grindstone. Such a grindstone can effectively remove the fixed abrasive grains from the surface of the fixed abrasive grain wire 2, and the workpiece W can be drawn out while more reliably prevented from being caught by the fixed abrasive grain wire 2.

Further, the inventive wire saw 1 preferably includes a controller configured to control drawing of the workpiece W from the wire row 30 through a portion where the fixed abrasive grains are removed from the fixed abrasive grain wire 2 by the unit configured to remove fixed abrasive grains. Such a controller controls the positions where the workpiece W is drawn out through portions on the surfaces of the fixed abrasive grain wire 2 from which the fixed abrasive grains are removed. This enables drawing of the workpiece W by further reliably preventing catching by the fixed abrasive grain wire 2.

Next, the inventive method for slicing a workpiece will be described based on an example where the above-described inventive wire saw is used. First, as shown in FIG. 1, the fixed abrasive grain wire 2 having abrasive grains secured to the surface is wound around the multiple grooved rollers 3, 3′ to form the wire row 30. Then, the fixed abrasive grain wire 2 is allowed to reciprocatively travel in the axial direction of the fixed abrasive grain wire 2 by the grooved roller-driving motor 10. Further, an appropriate tension is applied to the fixed abrasive grain wire 2 by the tension-adjusting mechanisms 4, 4′. A coolant supplied from the coolant-supplying mechanism 6 is supplied, while the fixed abrasive grain wire 2 is traveled in reciprocating directions by driving motors 11, 11′. The columnar workpiece W is fed to the wire row 30 for slicing by the workpiece-feeding mechanism 5. Thereby, the workpiece W is sliced at multiple positions aligned in the axial direction thereof simultaneously.

The inventive method for slicing a workpiece includes a fixed-abrasive-grain removal step of, after the workpiece W is sliced and before the workpiece W is drawn out from the wire row 30, pressing the wire row 30 against the grindstone 21 of the bonding member 20, which is provided between the workpiece W and the workpiece holder 14, to remove the fixed abrasive grains from the fixed abrasive grain wire 2 while the fixed abrasive grain wire 2 is reciprocatively traveling.

According to such a method for slicing a workpiece, after the workpiece is sliced and before the workpiece is drawn out through the wire row, fixed abrasive grains are removed from the fixed abrasive grain wire surface. Thus, a gap (clearance) is successfully formed between the wire and the workpiece. Moreover, the removal of the fixed abrasive grains having cutting ability satisfactorily prevents the fixed abrasive grain wire from cutting into the workpiece. By these, the workpiece is successfully drawn out without being caught by the fixed abrasive grain wire, and saw mark formation and wire break of the fixed abrasive grain wire can be avoided, which otherwise occur if the workpiece is caught by the fixed abrasive grain wire.

### EXAMPLE

Hereinafter, the present invention will be specifically described with reference to Experimental Examples, Example, and Comparative Example, but the present invention is not limited thereto.

### Experimental Example 1

The same wire saw as the inventive wire saw was used to examine a change in wire outer diameter when the wire row was pressed against the grindstone and the fixed abrasive grain wire was reciprocally moved. In this event, a holder 214 as shown in FIG. 4 was used, which is constituted of a holding portion 212 and a plate 213 bonded to a grindstone 221. Additionally, the fixed abrasive grain wire used had diamond abrasive grains as the fixed abrasive grains secured thereto. Table 1 below shows the employed fixed abrasive grain wire, grindstone, and test common conditions.

TABLE 1

| | | |
|---|---|---|
| Fixed | core wire diameter | 0.140 mm |
| abrasive | diamond abrasive | 10 to 20 μm |
| grain wire | grains | |
| | wire outer diameter | 0.174 mm |
| | (nominal) | |
| | abrasive-grain fixing | through nickel |
| | method | electrodeposition |
| Grindstone | type | WA |
| | grit size | #200 |
| Test common | wire tension | 25N |
| conditions | | water + glycol |
| | coolant liquid type | mixture |
| | coolant flow rate | 150 L/min. |
| | coolant temperature | 23° C. |

With the grindstone 221 bonded to the plate 213 using an epoxy-based adhesive as shown in FIG. 4, the wire rate was changed within 10 to 400 m/min. under conditions that the fixed abrasive grain wire 202 was pressed against the grindstone 221 at a load of 120 g/line and the wire was reciprocated 400 times.

Table 2 shows the result of Experimental Example 1 by relative values, given that the amount of the wire outer diameter reduced at a wire rate of 100 m/min. was set as 100.

TABLE 2

| | | |
|---|---|---|
| Wire rate | 10 | 88 |
| [m/min.] | 50 | 97 |
| | 100 | 100 |
| | 200 | wire was broken |
| | 400 | wire was broken |

Relative values with the amount of the wire outer diameter reduced at 100 m/min. being taken as 100

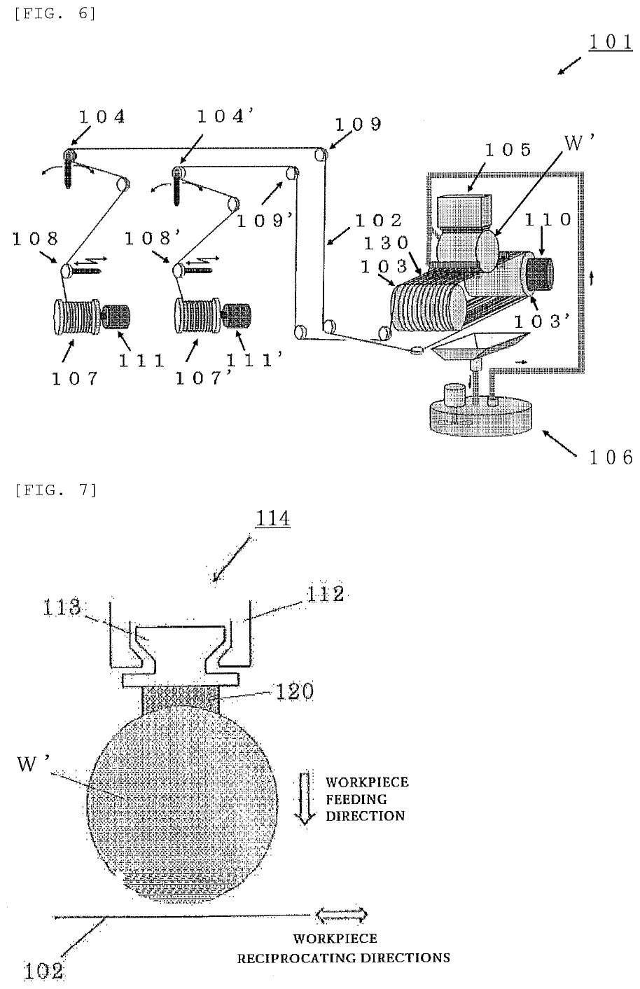

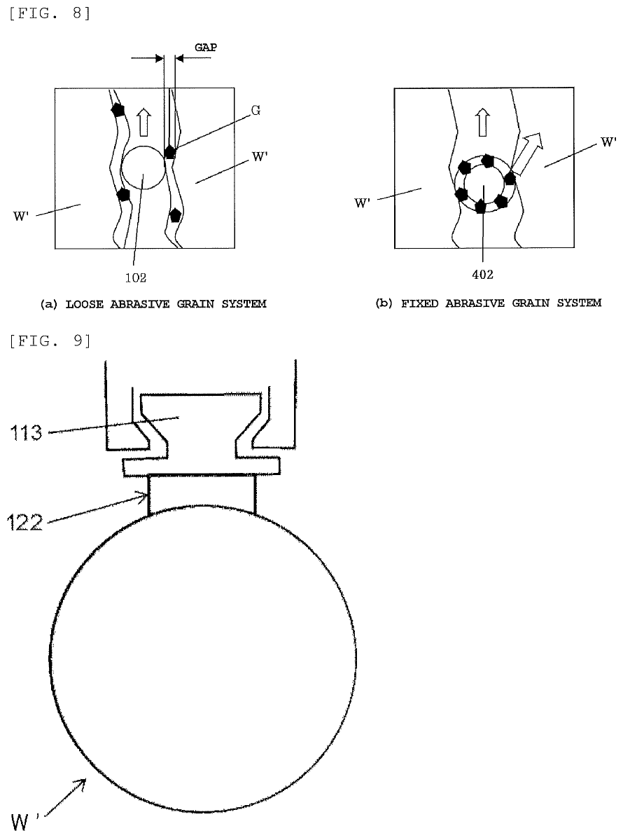

It was found from the result in Table 2 that the wire was broken when the wire rate exceeded 100 m/min. Further, FIG. 5 shows SEM observation results of the fixed abrasive grain wire before and after the reciprocal movement test. As FIG. 5, in the fixed abrasive grain wire after the reciprocal movement test (FIG. 5(b)), the diamond abrasive grains H were removed from the fixed abrasive grain wire before the reciprocal movement test (FIG. 5(a)), and only the core wire I of the fixed abrasive grain wire was observed. This revealed that the wire outer diameter was reduced because the diamond abrasive grains H on the fixed abrasive grain wire surface were removed.

### Experimental Example 2

The same wire saw as that in Experimental Example 1 was used to examine a change in wire outer diameter when the wire row was pressed against the grindstone and the fixed abrasive grain wire was reciprocally moved. Table 3 below shows the employed fixed abrasive grain wire, grindstone, and test common conditions. The grindstone was bonded in the same manner as in Experimental Example 1 (FIG. 4).

TABLE 3

| | | |
|---|---|---|
| Fixed | core wire diameter | 0.140 mm |
| abrasive | diamond abrasive | 10 to 20 μm |
| grain wire | grains | |
| | wire outer diameter | 0.174 mm |
| | (nominal) | |
| | abrasive-grain fixing | through nickel |
| | method | electrodeposition |
| Grindstone | type | WA |
| | grit size | #200 |
| Test common | wire tension | 25 N |
| conditions | coolant liquid type | water + glycol |
| | | mixture |
| | coolant flow rate | 150 L/min. |
| | coolant temperature | 23° C. |
| | wire rate | 100 m/min. |

Based on the result in Experimental Example 1, the wire rate was set at 100 m/min., but the load at which the fixed abrasive grain wire was pressed against the grindstone and the number of wire reciprocations were changed.

Table 4 shows the result of Experimental Example 2 by relative values, given that the amount of the wire outer diameter reduced under the following conditions was set as 100: the fixed abrasive grain wire was pressed against the grindstone at a load of 120 g/line and the wire was reciprocated 400 times.

TABLE 4

| | | Number of wire reciprocations | | |
|---|---|---|---|---|
| | | [number of times] | | |
| | | 400 | 800 | 3000 |
| Load of | 10 | 3 | 5 | 12 |
| pressing | 30 | 21 | 38 | 101 |
| wire | 60 | 47 | 85 | 102 |
| against | 120 | 100 | 103 | — |
| grindstone | 240 | 105 | 108 | — |
| [g/line] | | | | |

The amount of the wire outer diameter reduced under the following conditions was taken as 100: the load of pressing the wire against the grindstone was 120 g/line and the number of wire reciprocations was 400 times

The result in Table 4 revealed that if the load of pressing the fixed abrasive grain wire against the grindstone is not 30 g/line or more, the wire diameter is not reduced, in other words, the diamond abrasive grains are not sufficiently removed. Moreover, when the load was 120 g and 240 g, even if the number of wire reciprocations was increased, the amount of the wire outer diameter reduced hardly changed. This implies that after the diamond abrasive grains are removed, the abrasion of the wire core hardly proceeds, and the possibility of wire break by carrying out the present invention is quite low.

### Example and Comparative Example

As Example, the inventive wire saw and method for slicing a workpiece were used to slice and draw out a workpiece. Meanwhile, as Comparative Example, a general workpiece slicing method was used to slice and draw out a workpiece. As the workpieces sliced in these Example and Comparative Example, columnar silicon single crystal ingots each having a diameter of approximately 301 mm were used. Table 5 shows the test conditions in Example and Comparative Example.

TABLE 5

| | | | Comparative |
|---|---|---|---|
| | | Example | Example |
| Workpiece | diameter | 301 mm | |
| Bonding | material | resin + WA | resin |
| member | | grindstone | |
| | grindstone grit | #200 | — |
| | size | | |
| | adhesive | epoxy-based resin | |
| Grooved | roller pitch | 1001 μm | |
| roller | | | |
| Fixed | core wire diameter | 0.140 mm | |
| abrasive | diamond abrasive | 10 to 20 μm | |
| grain wire | grains | | |
| | wire outer | 0.174 mm | |
| | diameter (nominal) | | |
| | abrasive-grain | through nickel | |
| | fixing method | electrodeposition | |
| Coolant | liquid type | water + glycol mixture | |
| | flow rate | 150 L/min. | |
| | temperature | 23° C. | |
| Workpiece | wire tension | 25N | |
| slicing | wire travelling | up to 1500 m/min. | |
| conditions | rate | | |
| Conditions | wire tension | 25N | — |
| of pressing | wire travelling | 100 m/min. | — |
| wire | rate | | |
| against | load of pressing | | |
| grindstone | wire against | 120 g/line | — |
| and | grindstone | | |
| reciprocat- | Number of wire | 400 | — |
| ing wire | reciprocations | | |

| | | |
|---|---|---|
| Drawing | wire tension | 25N |
| conditions | wire rate | 5 m/min. at maximum |

In Example, the grindstone 21 was disposed between the resin 22 and the workpiece plate 13 as shown in FIG. 3. Meanwhile, in Comparative Example, only a resin 122 was adhered as the bonding member to the workpiece plate 113 as shown in FIG. 9. The workpieces W, W′ were bonded to the bonding members with an epoxy-based adhesive.

In Example, after the workpiece was sliced, the fixed abrasive grain wire was pressed against the grindstone and reciprocally moved, and then the workpiece was drawn out. In Comparative Example, immediately after the workpiece was sliced, the workpiece was drawn out. Table 6 shows the results of Example and Comparative Example.

TABLE 6

| | | Whether or not |
|---|---|---|
| | Whether or not | saw mark was |
| | wire was broken | formed |
| Example | wire was not | no saw mark |
| | broken | |
| Comparative | wire was broken | saw mark was |
| Example | | formed |

From the results of Example and Comparative Example as shown in Table 6, in Example, the fixed abrasive grain wire was not broken when the workpiece was drawn out, and no saw mark was observed on the main surfaces of the sliced wafers, either. In contrast, in Comparative Example, the fixed abrasive grain wire was broken during the drawing out, and saw mark was observed on the main surfaces of the sliced wafers.

The results of Experimental Examples, Example, and Comparative Example revealed that the inventive wire saw and the inventive method for slicing a workpiece make it possible to draw out a workpiece without being caught by a fixed abrasive grain wire, and to avoid saw mark formation and wire break of the fixed abrasive grain wire, which would otherwise occur if the workpiece is caught by the fixed abrasive grain wire.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1.-6. (canceled)

7. A method for slicing a workpiece with a wire saw which includes a wire row formed by winding a fixed abrasive grain wire having abrasive grains secured to a surface thereof around a plurality of grooved rollers, the method comprising feeding a workpiece to the wire row for slicing the workpiece held by a workpiece holder with a bonding member bonded to the workpiece, while allowing the fixed abrasive grain wire to reciprocatively travel in an axial direction thereof, thereby slicing the workpiece at a plurality of positions aligned in an axial direction of the workpiece simultaneously,
wherein the bonding member has a grindstone as a part,
the method comprises, after the workpiece is sliced and before the workpiece is drawn out from the wire row, a fixed-abrasive-grain removal step of pressing the wire row against the grindstone to remove the fixed abrasive grains from the fixed abrasive grain wire while the fixed abrasive grain wire is reciprocatively traveling, and
in the fixed-abrasive-grain removal step, the fixed abrasive grain wire is traveled at a wire rate of 100 m/min. or less, and the wire row is pressed against the grindstone at a load of 30 g or more for each line of the fixed abrasive grain wire.

8. The method for slicing a workpiece according to claim 7, wherein a WA grindstone is used as the grindstone.

9. The method for slicing a workpiece according to claim 7, wherein the workpiece is drawn out from the wire row through a portion of the fixed abrasive grain wire from which the fixed abrasive grains have been removed in the fixed-abrasive-grain removal step.

10. The method for slicing a workpiece according to claim 8, wherein the workpiece is drawn out from the wire row through a portion of the fixed abrasive grain wire from which the fixed abrasive grains have been removed in the fixed-abrasive-grain removal step.

11. A wire saw comprising:
a wire row formed of a fixed abrasive grain wire which has abrasive grains secured to a surface thereof and is wound around a plurality of grooved rollers; and
a workpiece-feeding mechanism configured to press a workpiece against the wire row, the workpiece being held by a workpiece holder with a bonding member bonded to the workpiece, wherein
the workpiece-feeding mechanism feeds the workpiece for slicing to the wire row while the fixed abrasive grain wire reciprocatively travels in an axial direction thereof, thereby slicing the workpiece at a plurality of positions aligned in an axial direction of the workpiece simultaneously,
the bonding member has a grindstone as a part,
the wire saw comprises a unit configured to remove fixed abrasive grains from the fixed abrasive grain wire by pressing the wire row against the grindstone while the fixed abrasive grain wire is reciprocatively traveling, and
when the fixed abrasive grains are removed, the fixed abrasive grain wire is traveled at a wire rate of 100 m/min. or less, and the wire row is pressed against the grindstone at a load of 30 g or more for each line of the fixed abrasive grain wire.

12. The wire saw according to claim 11, wherein the grindstone is a WA grindstone.

13. The wire saw according to claim 11, comprising a controller configured to control drawing of the workpiece from the wire row through a portion where the fixed abrasive grains have been removed from the fixed abrasive grain wire by the unit configured to remove fixed abrasive grains.

14. The wire saw according to claim 12, comprising a controller configured to control drawing of the workpiece from the wire row through a portion where the fixed abrasive grains have been removed from the fixed abrasive grain wire by the unit configured to remove fixed abrasive grains.
